(19) United States
(12) Patent Application Publication
(10) Pub. No.: US 2024/0143893 A1
(43) Pub. Date: May 2, 2024

(54) MODELING METHOD AND MODELING SYSTEM FOR OPTICAL PROXIMITY CORRECTION MODEL, AND OPTICAL PROXIMITY CORRECTION METHOD

(71) Applicant: HUAHONG GRACE SEMICONDUCTOR MANUFACTURING CORPORATION, Shanghai (CN)

(72) Inventor: Lei WANG, Shanghai (CN)

(21) Appl. No.: 18/324,726

(22) Filed: May 26, 2023

(30) Foreign Application Priority Data
Oct. 26, 2022 (CN) 202211320040.5

(51) Int. Cl. G06F 30/398; G06F 30/392

(52) U.S. Cl. CPC G06F 30/398; G06F 30/392

(57) ABSTRACT

A modeling method and a modeling system for an optical proximity correction (OPC) model and an OPC method based on the OPC model are disclosed. During the creation of the OPC model, variables related to pattern density of a test pattern are added. As a result, the created innovative OPC model includes a mapping relationship between a critical dimension of the pattern and the pattern density-related variables. After that, the OPC model is used to determine critical dimension (CD) distortion of the test pattern in environments with different pattern densities, which is then compared with a designed CD for the test pattern, thereby determining an OPC correction amount for the test pattern. In this way, accurate OPC correction can be achieved, resulting in an improved process window for the layout and effectively increased yield of the product.

### CROSS-REFERENCES TO RELATED APPLICATION

This application claims the priority of Chinese patent application number 202211320040.5, filed on Oct. 26, 2022, the entire contents of which are incorporated herein by reference.

### TECHNICAL FIELD

The present invention relates to the field of semiconductor technology and, in particular, to a modeling method for an optical proximity correction (OPC) model and an OPC method.

### BACKGROUND

Optical proximity correction (OPC) technology has been widely used in the large-scale production of deep submicron integrated circuits. Layouting of critical tiers for 90-nm and lower technology nodes generally employs model-based OPC, which essentially involves simulating post-exposure or post-etch shapes and dimensions of patterns using a model, making corrections based on deviations of the simulation data from target data and deriving a final reticle pattern through several iterations.

Correction models and menus obtained from conventional OPC modeling methods do not reflect the actual influence of pattern density on pattern accuracy. Therefore, conventional OPC modeling places no requirements on pattern density during data collection. However, when a photolithography process approaches its resolution limit, the influence of pattern density, in particular local pattern density, cannot be ignored. Obviously, the conventional OPC modeling that does not take pattern density into account inevitably suffers from the problem that the corrected pattern does not meet the design requirements in terms of both critical dimension (CD) and process window.

### SUMMARY OF THE INVENTION

It is an objective of the present invention to provide a modeling method for an OPC model, which takes into account pattern density, as well as an OPC method based on the model. With these methods, a corrected pattern can meet the design requirements in terms of both critical dimension (CD) and process window, resulting in enhanced product consistency.

To this end, in a first aspect, the present invention provides a modeling method for an OPC model, OPC method may include: configuring N sets of OPC test patterns with different pattern densities, where N is greater than or equal to 2; and utilizing the OPC test patterns to create the OPC model including variation of a CD of a test pattern with pattern density.

Additionally, each of the sets of OPC test patterns with different pattern densities may at least include a primary pattern Pᵢ and at least one auxiliary pattern Aᵢ each provided around the primary pattern Pᵢ at a distinct designed distance from the primary pattern Pᵢ.

Additionally, utilizing the OPC test patterns to create the OPC model including variation of a CD of a test pattern with pattern density may include: collecting wafer data for each of the sets of OPC test patterns with different pattern densities, which includes an actual on-wafer CD of the primary pattern Pᵢ, and based on the wafer data, establishing a mapping relationship reflecting variation of the actual on-wafer CD of the primary pattern Pᵢ with pattern density of OPC test patterns, as the OPC model.

Additionally, the pattern density may include local pattern density or global pattern density.

Additionally, the local pattern density may be a percentage of an aggregate area of a plurality of auxiliary patterns Aᵢ within a predetermined region in the area of the predetermined region.

Additionally, the predetermined region may have a size of X*Y, where X may range from 30 nm to 1000 nm, and Y may range from 30 nm to 1000 nm.

Additionally, the mapping relationship reflecting variation of the actual on-wafer CD of the primary pattern Pᵢ with pattern density of OPC test patterns may include: a function describing variation of the actual on-wafer CD of the primary pattern Pᵢ with a designed area of an auxiliary pattern Aᵢ and a designed distance between the primary pattern Pᵢ and the auxiliary pattern Aᵢ; and/or a function describing variation of the actual on-wafer CD of the primary pattern Pᵢ with a ratio of a designed area of an auxiliary pattern Aᵢ within a predetermined region to the area of the predetermined region.

Additionally, the square root of the designed area of the auxiliary pattern Aᵢ may be greater than 10 times the CD of the primary pattern Pᵢ.

Additionally, the distance between the primary pattern Pᵢ and the auxiliary pattern Aᵢ may be not greater than 100 times the CD of the primary pattern Pᵢ.

In a second aspect, on the basis of the same inventive concept as the modeling method, the present invention also provides a modeling system for an OPC model. Specifically, the modeling system may be used to implement the modeling method as defined above and may include the following modules: an OPC test pattern configuration module for configuring N sets of OPC test patterns with different pattern densities, where N is greater than or equal to 2, each of the sets of OPC test patterns with different pattern densities at least including a primary pattern Pᵢ and at least one auxiliary pattern Aᵢ each provided around the primary pattern Pᵢ at a distinct designed distance therefrom; and a model creation module for collecting wafer data for each of the sets of OPC test patterns with different pattern densities, which includes an actual on-wafer CD of the primary pattern Pᵢ, and based on the wafer data, establishing a mapping relationship reflecting variation of the actual on-wafer CD of the primary pattern Pᵢ with pattern density of OPC test patterns, as the OPC model.

In a third aspect, on the basis of the same inventive concept as the modeling method, the present invention also provides an OPC method, which may include the following steps: creating an OPC model using a modeling method as defined above, which adds a mapping relationship between a CD of a pattern and pattern density-related variables; determining a test layout corresponding to a prefabricated layout, which has at least one pattern to be corrected, and determining pattern density of the pattern to be corrected in the test layout using a predefined pattern detection strategy; and based on the determined pattern density and the mapping relationship in the OPC model, determining a CD correction amount for the pattern to be corrected for the current OPC run and performing an OPC operation on the pattern to be corrected according to the CD correction amount.
Additionally, the mapping relationship that adds the mapping relationship between the CD of the pattern and the pattern density-related variables may include:
a function describing variation of an actual on-wafer CD of a primary pattern Pᵢ with a designed area of an auxiliary pattern and a designed distance between the primary pattern Pᵢ and the auxiliary pattern Aᵢ; and/or a function describing variation of an actual on-wafer CD of a primary pattern Pᵢ with a ratio of a designed area of an auxiliary pattern Aᵢ within a predetermined region to the area of the predetermined region.

Additionally, determining the pattern density of the pattern to be corrected in the test layout using the predefined pattern detection strategy may include: determining a surrounding pattern of the pattern to be corrected, the area of which is greater than a predetermined threshold, and determining the area of the surrounding pattern and a distance between the surrounding pattern and the pattern to be corrected.

Additionally, determining the CD correction amount for the pattern to be corrected for the current OPC run based on the determined pattern density and the mapping relationship in the OPC mode may include: inputting the area and the distance to the function in the OPC model that describes variation of an actual on-wafer CD of a primary pattern Pᵢ with a designed area of an auxiliary pattern Aᵢ and a designed distance between the primary pattern Pᵢ and the auxiliary pattern Aᵢ and taking a difference between an output of the function and a designed CD for the pattern to be corrected as the CD correction amount for the pattern to be corrected for the current OPC run.

Additionally, determining the pattern density of the pattern to be corrected in the test layout using the predefined pattern detection strategy may include: determining a region encompassing the pattern to be corrected and a plurality of surrounding patterns each spaced from the pattern to be corrected at a certain distance; and determining the area of the determined region and an aggregate area of all the surrounding patterns of the pattern to be corrected contained in the predetermined region.

Additionally, determining the CD correction amount for the pattern to be corrected for the current OPC run based on the determined pattern density and the mapping relationship in the OPC mode may include: inputting the area of the determined region and the aggregate area of all the surrounding patterns of the pattern to be corrected contained in the predetermined region to the function in the OPC model that describes variation of an actual on-wafer CD of a primary pattern Pᵢ with a ratio of a designed area of an auxiliary pattern Aᵢ within a predetermined region to the area of the predetermined region and taking a difference between an output of the function and the designed CD for the pattern to be corrected as the CD correction amount for the pattern to be corrected for the current OPC run.

Additionally, determining the CD correction amount for the pattern to be corrected for the current OPC run based on the determined pattern density and the mapping relationship in the OPC mode may include: inputting the area, the distance, the area of the determined region and the aggregate area of all the surrounding patterns of the pattern to be corrected contained in the predetermined region into the OPC model and taking a difference between an output of the OPC model and the designed CD for the pattern to be corrected as the CD correction amount for the pattern to be corrected for the current OPC run.

Additionally, the square root of the area of the surrounding pattern of the pattern to be corrected may be greater than 10 times the CD of the pattern to be corrected.

Additionally, the distance between the surrounding pattern and the pattern to be corrected may be not greater than 100 times the CD of the pattern to be corrected.

In a fourth aspect, on the basis of the same inventive concept as the modeling method, the present invention also provides an OPC system. Specifically, the correction system may be used to implement the OPC method as defined above and may include the following modules: a modeling module for creating an OPC model using a modeling method as defined above, which adds a mapping relationship between a critical dimension (CD) of a pattern and pattern density-related variables; a pattern density determination module for determining a test layout corresponding to a prefabricated layout, which has at least one pattern to be corrected, and determining pattern density of the pattern to be corrected in the test layout using a predefined pattern detection strategy; and a correction module for determining, based on the determined pattern density and the mapping relationship in the OPC model, a CD correction amount for the pattern to be corrected for the current OPC run and performing an OPC operation on the pattern to be corrected according to the CD correction amount.

In a fifth aspect, on the basis of the same inventive concept as the modeling method and the OPC method, the present invention also provides an electronic device including a processor, a communication interface, a storage member and a communication bus, wherein the processor, the communication interface and the storage member communicate one another through the communication bus.

The storage member is used to store a computer program thereon.

The processor is used to, when executing the program stored on the storage member, implement the steps in the modeling method or the steps in the OPC method.

In a sixth aspect, embodiments of the present invention also provide a computer-readable storage medium storing therein a computer program, which, when executed by a processor, implements the steps in the modeling method or the steps in the OPC method.

Compared with the prior art, the present invention has at least one of the following advantages:

It provides a modeling method for an OPC model and an OPC method based on the OPC model, in which during the creation of the OPC model, variables related to pattern density of a test pattern are added. As a result, the created innovative OPC model includes a mapping relationship between the pattern's CD and the pattern density-related variables. After that, the OPC model is used to determine CD distortion of the test pattern in environments with different pattern densities, which is then compared with a designed CD for the test pattern, thereby determining an OPC correction amount for the test pattern. In this way, accurate OPC correction can be achieved, resulting in an improved process window for the layout and effectively increased yield of the product.

### BRIEF DESCRIPTION OF THE DRAWINGS

FIG. 1 is a schematic flow diagram of a modeling method for an OPC model according to an embodiment of the present invention.

FIG. 2 is a schematic diagram showing the structure of an OPC test pattern arrangement for taking into account the influence of one-dimensional pattern density around a test pattern on a CD thereof, in which an auxiliary pattern is arranged around a primary pattern, according to an embodiment of the present invention.

FIG. 3 is a schematic diagram showing the structure of an OPC test pattern arrangement for taking into account the influence of two-dimensional pattern density of a surrounding region of a test pattern on a CD thereof, in which a predetermined region encompasses a primary pattern, according to an embodiment of the present invention.

FIG. 4 is a schematic diagram showing the structure of a modeling system for an OPC model according to an embodiment of the present invention.

FIG. 5 is a schematic flow diagram of an OPC method according to an embodiment of the present invention.

FIG. 6 is a schematic diagram showing the structure of an OPC system according to an embodiment of the present invention.

### DETAILED DESCRIPTION

As described in the Background section, correction models and menus obtained from conventional OPC modeling methods do not reflect the actual influence of pattern density on pattern accuracy. Therefore, conventional OPC modeling places no requirements on pattern density during data collection. However, when a photolithography process approaches its resolution limit, the influence of pattern density, in particular local pattern density, cannot be ignored. Obviously, the conventional OPC modeling that does not take pattern density into account inevitably suffers from the problem that the corrected pattern does not meet the design requirements in terms of both critical dimension (CD) and process window.

In view of this, the inventor proposes, during the creation of an OPC model, first defining a set of pattern density-related variables and then mapping the pattern density-related variables to target correction parameters through analyzing sample simulation data corresponding to predefined N sets of OPC test patterns. In this way, the created OPC model additionally includes the pattern density-related variables. Based on this OPC model, as well as on collected data of pattern density of a target pattern to be corrected that varies with other patterns around the target pattern, a target correction amount (e.g., CD) for the target pattern to be corrected can be determined.

Based on this concept, the present invention provides a modeling method for an OPC model, which takes into account pattern density, as well as an OPC method based on the model. With these methods, a corrected pattern can meet the design requirements in terms of both CD and process window, resulting in enhanced product consistency.

The proposed methods will be described in greater detail below with reference to the accompanying drawings and to specific embodiments. Advantages and features of the present invention will become more apparent from the following description. Note that the figures are provided in a very simplified form not necessarily drawn to exact scale and for the only purpose of facilitating easy and clear description of the embodiments. In the following description, numerous details are set forth so that a full understanding of the present invention may be acquired. However, the invention may be practiced in other forms than those described herein. Therefore, it is in no way limited to the particular embodiments described hereinafter.

As used herein and in the appended claims, the singular forms “a”, “an” and/or “the” are intended to include the plural forms as well, unless the context clearly indicates otherwise. In general, the terms “comprising” and “including” only imply the presence of expressly stated steps and elements, which do not constitute an exclusive list though, as other steps or elements may also be included. In the following detailed description of the embodiments, for ease of illustration, cross-sectional views of device structures may have been exaggerated in parts, rather than drawn to scale. Moreover, the schematic diagrams are merely exemplary and not intended to limit the scope of the invention in any sense. Further, in practical fabrication, sizes in a three-dimensional space, including lengths, widths and depths, should be included.

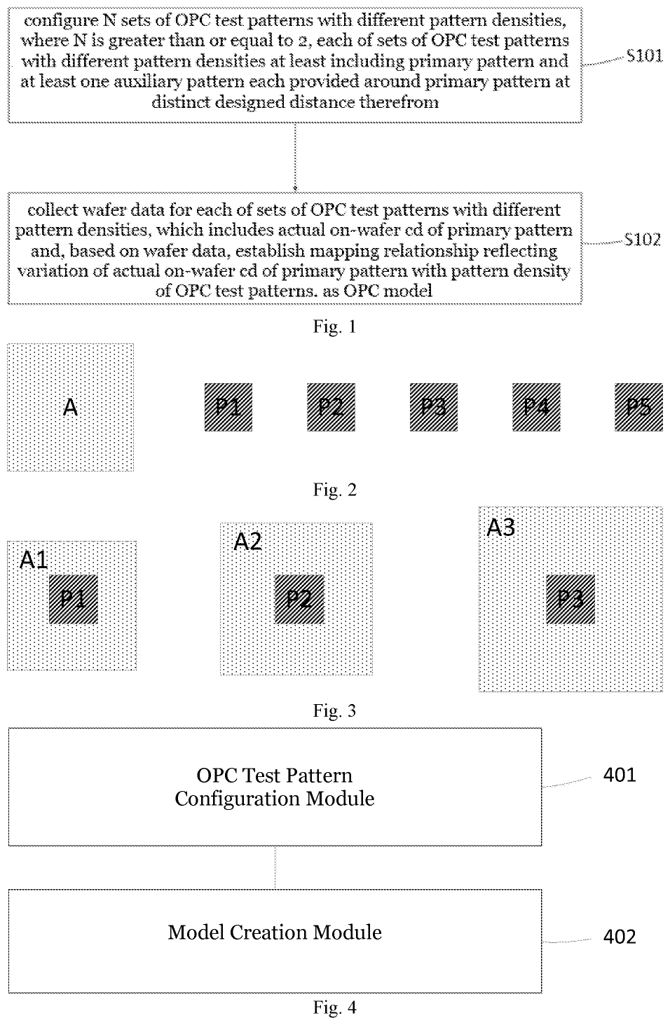

First of all, a modeling method for an OPC model according to the present invention will be described below. Reference is now made to FIG. 1, a schematic flow diagram of a modeling method for an OPC model according to an embodiment of the present invention. As shown, the method includes the steps as follows.

Step S101: Configure N sets of OPC test patterns with different pattern densities. N is greater than or equal to 2. Each of the sets of OPC test patterns with different pattern densities at least includes a primary pattern Pᵢ and at least one auxiliary pattern Aᵢ, each auxiliary pattern Aᵢ is arranged around the primary pattern Pᵢ at a distinct designed distance from the primary pattern Pᵢ.

Pattern density includes local pattern density or global pattern density. Local pattern density is defined as a percentage of an aggregate area of auxiliary patterns Aᵢ in a predetermined region to the area of the predetermined region. As an example, the predetermined region may have a size of X*Y. X may range from 30 nm to 1000 nm, such as 30 nm, 40 nm, 50 nm, 100 nm, 200 nm, 300 nm, 400 nm, 500 nm, 600 nm, 700 nm, 800 nm, 900 nm or 1000 nm. Alternatively, it may be in the range of 30 nm/40 nm/50 nm to 100 nm, 100 nm to 200 nm/300 nm/400 nm/500 nm/600 nm/700 nm/800 nm/900 nm/1000 nm, or any other range defined between any pair of the foregoing limit values. Likewise, Y may range from 30 nm to 1000 nm, such as 30 nm, 40 nm, 50 nm, 100 nm, 200 nm, 300 nm, 400 nm, 500 nm, 600 nm, 700 nm, 800 nm, 900 nm or 1000 nm. Alternatively, it may be in the range of 30 nm/40 nm/50 nm to 100 nm, 100 nm to 200 nm/300 nm/400 nm/500 nm/600 nm/700 nm/800 nm/900 nm/1000 nm, or any other range defined between any pair of the foregoing limit values.

In this embodiment, during the creation of the OPC model, it is necessary to take into account the influence of pattern density of one or more other patterns around a pattern to be corrected in the test layout with respect to the pattern to be corrected on a critical dimension (CD) of the pattern to be corrected. The influence may be either one-dimensional or two-dimensional in the X and Y directions in a region of the test layout surrounding the pattern to be corrected. Accordingly, in implementations of the present invention, there are provided individual OPC modeling modes for multiple scenarios of the different types of influence (one-dimensional and two-dimensional) on the pattern to be corrected.
Mode 1: Influence of only one-dimensional pattern density of other patterns around the pattern to be corrected with respect to the pattern to be corrected on the CD thereof in the test layout is considered. OPC test patterns for OPC modeling are assumed as follows: as shown in FIG. 2, P₁, P₂ . . . , Pᵢ, . . . , Pₙ represent a test pattern equivalent to the pattern to be corrected in the test layout, called a primary pattern, while each test pattern around the primary pattern Pᵢ is equivalent to a surrounding pattern of the pattern to be corrected in the test layout, called an auxiliary pattern Aᵢ.

It is to be noted that, in the modeling process, multiple sets of sample data are subjected to exposure, and each set of sample data is analyzed. Moreover, the multiple sets of sample data are used to correct the OPC model, eventually deriving a mapping relationship as the final OPC model, which reflects variation of an actual on-wafer CD of the primary pattern Pᵢ with pattern density of OPC test patterns.

As an example, during sample data training for OPC modeling, an auxiliary pattern Aᵢ may be arranged around the primary pattern Pᵢ, and the area of the auxiliary pattern Aᵢ and its distance to the primary pattern Pᵢ may be varied. In this way, N sets of OPC test patterns with different one-dimensional pattern densities can be obtained. As an example, the modeling process may require at least two such sets with different pattern densities. That is, N is greater than or equal to 2. FIG. 2 shows 5 sets of OPC test patterns, i.e., A and P₁, A and P₂, A and P₃, A and P₄, A and P₅, as an example. For ease of modeling, the primary pattern P₁-P₅ may maintain a constant designed area (which is a theoretical initial area set by the designer for the purpose of testing), the primary pattern P₁-P₅ may be arranged at different distances from the auxiliary pattern A. It would be appreciated that, although the auxiliary pattern A in the 5 sets of OPC test patterns are shown in FIG. 2 as maintaining a constant area as an example, it may also be varied in area in other examples.
Mode 2: Only two-dimensional influence in the X and Y directions in a region of the test layout surrounding the pattern to be corrected on the CD thereof is considered. OPC test patterns for OPC modeling are assumed as follows: as shown in FIG. 3, P₁, P₂ . . . Pᵢ, . . . , Pₙ represent a test pattern equivalent to the pattern to be corrected in the test layout, called a primary pattern, while all other test patterns in a region Aᵢ surrounding the primary pattern Pᵢ are equivalent to surrounding patterns of the pattern to be corrected in the test layout, called auxiliary patterns.

It is to be noted that, for the primary pattern Pᵢ, since Mode 2 considers the influence of pattern density of all patterns within a determined region surrounding the primary pattern Pᵢ, herein, the pattern density for the primary pattern Pᵢ is defined as a percentage of an aggregate area of all the OPC test patterns within the determined region to the area of this region, as an example. Moreover, since the aggregate area of all the auxiliary patterns within the region Aᵢ is considered, herein, not all auxiliary patterns in Aᵢ are depicted individually. Rather, for general description along with the one-dimensional pattern density, herein, both the surrounding region of the primary pattern Pᵢ and the auxiliary patterns therein are denoted as Aᵢ.

As an example, during sample data training for OPC modeling, a region Aᵢ surrounding the primary pattern Pᵢ may be determined, and an aggregate area of auxiliary patterns in the region Aᵢ and its ratio to the area of the region Aᵢ may be varied. In this way, N sets of OPC test patterns with different two-dimensional pattern densities can be obtained. As an example, the modeling process may require at least two such sets with different pattern densities. That is, N is greater than or equal to 2. FIG. 3 shows 3 sets of OPC test patterns, namely, A₁ and P₁, A₂ and P₂, A₃ and P₃, as an example. For ease of modeling, the primary pattern P₁-P₃ may maintain a constant designed area (which is a theoretical initial area set by the designer for the purpose of testing), while an aggregate area of P₁-P₃ and all auxiliary patterns in the region A₁-A₃ and a ratio of them may be varied.
Mode 3: Both one-dimensional influence of one or more patterns around the pattern to be corrected and two-dimensional influence in the X and Y direction in a region of the test layout surrounding the pattern to be corrected on the CD thereof are considered. That is, Mode 3 is a combination of Modes 1 and 2.

It is to be noted that, in Modes 1, 2 and 3 as described above, the square root of a designed area of each auxiliary pattern is desired to be not greater than 10 times the CD of the primary pattern Pᵢ. Specifically, the former may be 1 time, 2 times, 3 times, 4 times, 5 times, 6 times, 7 times, 8 times, 9 times or 10 times the latter. Moreover, each auxiliary pattern may be spaced from the primary pattern Pᵢ at a maximum allowable distance that is not greater than 100 times (i.e., ≤100 times) the CD of the primary pattern Pᵢ.

Step S102: Collect wafer data for each of the sets of OPC test patterns with different pattern densities, which includes an actual on-wafer CD of the primary pattern Pᵢ, and based on the wafer data, establish a mapping relationship reflecting variation of the actual on-wafer CD of the primary pattern Pᵢ with pattern density of OPC test patterns, as the OPC model.

In this embodiment, after the N sets of test patterns with different pattern densities are configured in Step S101, each set of OPC test patterns may be exposed on a wafer, and an actual CD on the wafer of the primary pattern Pᵢ may be determined. Subsequently, from the actual on-wafer CDs of the primary pattern Pᵢ resulting from the N sets of OPC test patterns and the respective pattern densities thereof, a mapping relationship reflecting variation of the actual on-wafer CD of the primary pattern Pᵢ with pattern density of OPC test patterns can be obtained as the OPC model. This OPC model obtained from the modeling method of the present invention takes into account pattern density.

As an example, the mapping relationship reflecting variation of the actual on-wafer CD of the primary pattern Pᵢ with pattern density of OPC test patterns may include a function describing variation of the actual on-wafer CD of the primary pattern Pᵢ with a designed area of an auxiliary pattern Aᵢ and a designed distance between the primary pattern Pᵢ and the auxiliary pattern Aᵢ.

As another example, the mapping relationship reflecting variation of the actual on-wafer CD of the primary pattern Pᵢ with pattern density of OPC test patterns may include a function describing variation of the actual on-wafer CD of the primary pattern Pᵢ with a ratio of a designed area of an auxiliary pattern Aᵢ in a predetermined region to the area of the predetermined region.

As yet another example, the mapping relationship reflecting variation of the actual on-wafer CD of the primary pattern Pᵢ with pattern density of OPC test patterns may include a function describing variation of the actual on-wafer CD of the primary pattern Pᵢ with a designed area of an auxiliary pattern Aᵢ and a designed distance between the primary pattern Pᵢ and the auxiliary pattern Aᵢ and a function describing variation of the actual on-wafer CD of the primary pattern Pᵢ with a ratio of a designed area of an auxiliary pattern Aᵢ in a predetermined region to the area of the predetermined region.

According to the present invention, since the modeling process additionally takes into account variables related to density of test patterns, the created innovative OPC model includes a mapping relationship between a pattern's CD and the pattern density-related variables. It would be appreciated that the present invention proposes a concept of taking into account the influence of pattern density-related variables on the correction of a pattern's CD during the creation of an OPC model. The mapping relationships as described above are merely several examples of the present invention, and any modeling methods taking into account the influence of pattern density-related variables on the correction of a pattern's CD during the creation of an OPC model are intended to fall within the scope of the present invention.

On the basis of the above-discussed modeling method, embodiments of the present invention also provide a modeling system for an OPC model. FIG. 4 is a schematic diagram showing the structure of a modeling system for an OPC model according to an embodiment of the present invention. The modeling system includes:
an OPC test pattern configuration module 401 for configuring N sets of OPC test patterns with different pattern densities, where N is greater than or equal to 2, each of the sets of OPC test patterns with different pattern densities at least including a primary pattern Pᵢ and at least one auxiliary pattern Aᵢ each provided around the primary pattern Pᵢ at a distinct designed distance therefrom; and
a model creation module 402 for collecting wafer data for each of the sets of OPC test patterns with different pattern densities, which includes an actual on-wafer CD of the primary pattern Pᵢ, and based on the wafer data, establishing a mapping relationship reflecting variation of the actual on-wafer CD of the primary pattern Pᵢ with pattern density of OPC test patterns, as the OPC model.

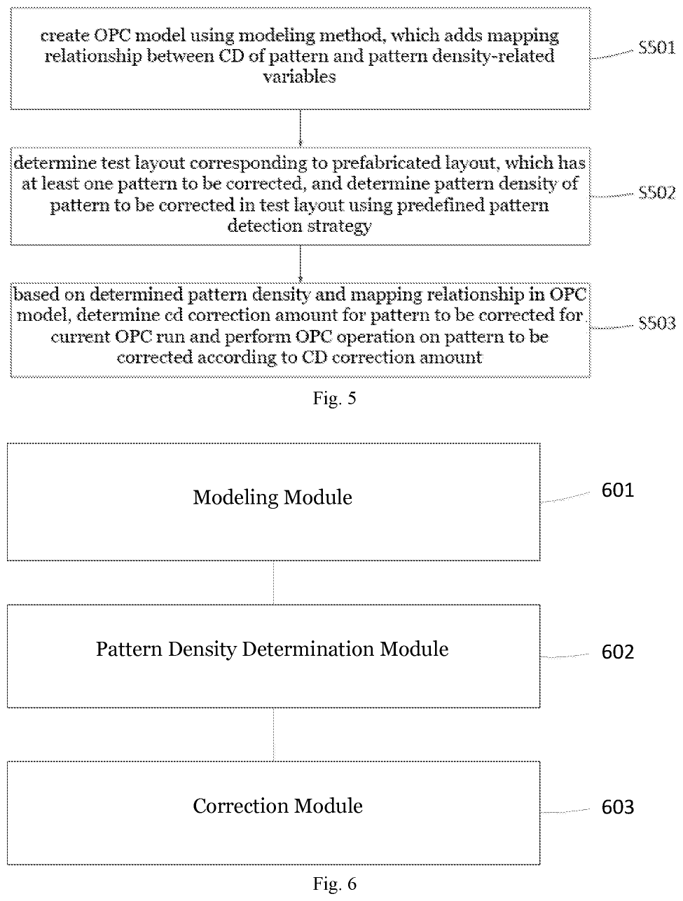

Further, on the basis of the same inventive concept as the above-discussed modeling method, the present invention also provides a correction method based on the OPC model. As shown in FIG. 5, the correction method may specifically include the steps as follows.

Step S501: Create an OPC model using the modeling method as defined above, which adds a mapping relationship between a pattern's CD and pattern density-related variables.

The mapping relationship between the pattern's CD and the pattern density-related variables may include: a function describing variation of an actual on-wafer CD of a primary pattern Pᵢ with a designed area of an auxiliary pattern Aᵢ and a designed distance between the primary pattern Pᵢ and the auxiliary pattern Aᵢ and/or a function describing variation of the actual on-wafer CD of the primary pattern Pᵢ with a ratio of a designed area of an auxiliary pattern Aᵢ in a predetermined region to the area of the predetermined region.

Step S502: Determine a test layout corresponding to a prefabricated layout, which has at least one pattern to be corrected, and determine pattern density of the pattern to be corrected in the test layout using a predefined pattern detection strategy.

In this embodiment, after the OPC model that adds the mapping relationship is created, a test layout to be corrected may be determined. The test layout may include a plurality of patterns to be corrected. The correction of only one pattern to be corrected in the test layout using the OPC model created in accordance with the present invention will be described herein as an example. The OPC model created using the modeling method of the present invention may be based on one-dimensional pattern density, or two-dimensional pattern density, or both. Accordingly, for these three cases, in different implementations of the present invention, the three approaches for determining the pattern density of the pattern to be corrected as described below may be employed.
Approach 1: Determine a surrounding pattern of the pattern to be corrected, the area of which is greater than a predetermined threshold, and determine the area of the surrounding pattern and a distance between the surrounding pattern and the pattern to be corrected.
Approach 2: Determine a region encompassing the pattern to be corrected and a plurality of surrounding patterns each spaced from the pattern to be corrected at a certain distance and determine the area of the determined region and an aggregate area of all the surrounding patterns.
Approach 3: Determine a surrounding pattern of the pattern to be corrected, the area of which is greater than a predetermined threshold, and determine the area of the surrounding pattern and a distance between the surrounding pattern and the pattern to be corrected; and then determine a region encompassing the pattern to be corrected and a plurality of surrounding patterns each spaced from the pattern to be corrected at a certain distance and determine the area of the determined region and an aggregate area of all the surrounding patterns.

It is to be noted that the pattern detection strategy employed in Modes 1, 2 and 3 may be an existing algorithm available in the OPC model menu for calculating the distance from a pattern of interest to a large-area pattern near the pattern of interest and/or pattern density of patterns within a certain region surrounding a pattern of interest.

Step S503: Based on the determined pattern density and the mapping relationship in the OPC model, determine a CD correction amount for the pattern to be corrected for the current OPC run and perform an OPC operation on the pattern to be corrected according to the CD correction amount.

In this embodiment, after the pattern density of the pattern to be corrected, i.e., the area of the surrounding pattern that is greater than the predetermined threshold and the distance between the surrounding pattern and the pattern to be corrected (first pattern density) and/or the area of the predetermined region and the aggregate area of all the surrounding patterns in the predetermined region (second pattern density), is determined in Step S502, the first pattern density and/or the second pattern density may be input to the OPC model created in accordance with the present invention. In this way, a CD correction amount for the pattern to be corrected for the current OPC run may be determined, and an OPC operation may be carried out on the pattern to be corrected according to the CD correction amount.

Specifically, the area and distance may be input to a function in the OPC model, which reflects variation of an actual on-wafer CD of a primary pattern Pᵢ with a designed area of an auxiliary pattern Aᵢ and a designed distance between the primary pattern Pᵢ and the auxiliary pattern Aᵢ, and the difference between an output of the function and a designed CD for the pattern to be corrected may be taken as the CD correction amount for the pattern to be corrected for the current OPC run.

Alternatively, the area of the predetermined region and the aggregate area of all the surrounding patterns in the predetermined region may be input to a function in the OPC model, which reflects variation of an actual on-wafer CD of a primary pattern Pᵢ with a ratio of a designed area of an auxiliary pattern in a predetermined region to the area of the predetermined region, and the difference between an output of the function and the designed CD for the pattern to be corrected may be taken as the CD correction amount for the pattern to be corrected for the current OPC run.

Still alternatively, the area, the distance, the area of the predetermined region and the aggregate area of all the surrounding patterns in the predetermined region may be input to the OPC model, and the difference between an output of the OPC model and the designed CD for the pattern to be corrected may be taken as the CD correction amount for the pattern to be corrected for the current OPC run.

The square root of the area of the surrounding pattern of the pattern to be corrected is greater than 10 times the CD of the pattern to be corrected, and the distance between the surrounding pattern and the pattern to be corrected is not greater than 100 times the CD of the pattern to be corrected.

In the OPC method of the present invention, the OPC model is used to determine CD distortion of a test pattern in environments with different pattern densities, which is then compared with a designed CD for the test pattern, thereby determining an OPC correction amount for the test pattern. In this way, accurate OPC correction can be achieved, resulting in an improved process window for the layout and effectively increased yield of the product.

Likewise, on the basis of the OPC method described above, the present invention also provides an OPC system for implementing the OPC method. Specifically, as shown in FIG. 6, the OPC system provided in the present invention may include:
a modeling module 601 for creating an OPC model using the modeling method as defined above, which adds a mapping relationship between a pattern's CD and pattern density-related variables;
a pattern density determination module 602 for determining a test layout corresponding to a prefabricated layout, which has at least one pattern to be corrected, and determining pattern density of the pattern to be corrected in the test layout using a predefined pattern detection strategy; and
a correction module 603 for determining, based on the determined pattern density and the mapping relationship in the OPC model, a CD correction amount for the pattern to be corrected for the current OPC run and performing an OPC operation on the pattern to be corrected according to the CD correction amount.

In summary, in the present invention, during the creation of an OPC model, variables related to pattern density of a test pattern are added. As a result, the created innovative OPC model includes a mapping relationship between the pattern's CD and the pattern density-related variables. After that, the OPC model is used to determine CD distortion of the test pattern in environments with different pattern densities, which is then compared with a designed CD for the test pattern, thereby determining an OPC correction amount for the test pattern. In this way, accurate OPC correction can be achieved, resulting in an improved process window for the layout and effectively increased yield of the product.

Embodiments of the present invention further provide an electronic device including a processor, a communication interface, a storage member and a communication bus. The processor, communication interface and the storage member can communicate with one another through the communication bus.

The storage member is used to store a computer program thereon.

The processor is used to, when executing the program stored on the storage member, implement a modeling method for an OPC model or a model-based OPC method according to embodiment of the present invention.

Specifically, the modeling method includes:
configuring N sets of OPC test patterns with different pattern densities, where N is greater than or equal to 2, each of the sets of OPC test patterns with different pattern densities at least including a primary pattern Pᵢ and at least one auxiliary pattern A each provided around the primary pattern Pᵢ at a distinct designed distance therefrom; and
collecting wafer data for each of the sets of OPC test patterns with different pattern densities, which includes an actual on-wafer CD of the primary pattern Pᵢ, and based on the wafer data, establishing a mapping relationship reflecting variation of the actual on-wafer CD of the primary pattern Pᵢ with pattern density of OPC test patterns, as the OPC model.

The OPC method includes:
creating an OPC model using a modeling method as defined above, which adds a mapping relationship between a critical dimension (CD) of a pattern and pattern density-related variables;
determining a test layout corresponding to a prefabricated layout, which has at least one pattern to be corrected, and determining pattern density of the pattern to be corrected in the test layout using a predefined pattern detection strategy; and
based on the determined pattern density and the mapping relationship in the OPC model, determining a CD correction amount for the pattern to be corrected for the current OPC run and performing an OPC operation on the pattern to be corrected according to the CD correction amount.

In addition, other embodiments of the modeling method or the OPC method that is implemented when the processor executes the program stored on the storage member are the same as described in the foregoing section of method embodiments and, therefore, need not be described in further detail herein.

The aforementioned communication bus may be incorporated in a control terminal and may be a peripheral component interconnect (PCI) bus, an extended industry standard architecture (EISA) bus or the like. The communication bus may include an address bus, a data bus, a control bus and the like. Although it is depicted as only one bolded line in the figure, this does not imply that there is only one bus or one type of bus.

The communication interface is used to enable communication between the electronic device and other devices.

The storage member may include a random access memory (RAM) or non-volatile memory (NVM) device, such as at least one magnetic memory device. Optional, the storage member may further include at least one memory device arranged away from the aforementioned processor.

The aforementioned processor may be a general-purpose processor. Examples may include: central processing units (CPUs), network processors (NPs) and the like; digital signal processors (DSPs), application-specific integrated circuits (ASICs), field-programmable gate arrays (FPGAs); and other programmable logic devices, discrete gates, transistor-based logic devices and discrete hardware components.

In further embodiments of the present invention, there is also provided a computer-readable storage medium storing therein instructions, which, when run on a computer, cause the computer to carry out the modeling method or OPC method according to any of the foregoing embodiments.

Some or all of the above embodiments may be implemented by software, hardware, firmware or any combination thereof. In case of a software implementation, some or all of them may be each provided in the form of a computer program product. The computer program product includes one or more computer instructions. When the computer program instructions are loaded and executed on a computer, all or some of the procedures or functions in the embodiments of the present invention are generated. The computer may be a general-purpose computer, a special-purpose computer, a computer network, or another programmable apparatus. The computer instructions may be stored in a computer-readable storage medium, or transmitted from one computer-readable storage medium to another computer-readable storage medium. For example, the computer instructions may be transmitted from one website location, computer, server or data center to another website location, computer, server or data center in a wired manner (e.g., through a coax cable, optical fiber, digital subscriber line (DSL)) or in a wireless manner (e.g., through infrared, radio, microwave or other transmission). The computer-readable storage medium may be any available medium that can be accessed by a computer, or may be a data storage device such as an integrated server including one or more available media or a data center. The available medium may be a magnetic medium (e.g., floppy disk, hard disk drive, magnetic tape), an optical medium (e.g., DVD), a semiconductor medium (e.g., solid state disk (SSD)), or the like.

It is to be noted that, as used herein, relational terms such as first and second, etc., are only used to distinguish one entity or operation from another entity or operation, and do not necessarily require or imply these entities having such an order or sequence. Moreover, the terms “include,” “including,” or any other variations thereof are intended to cover a non-exclusive inclusion within a process, method, article, or apparatus that includes a list of elements including not only those elements but also those that are not explicitly listed, or other elements that are inherent to such processes, methods, goods, or equipment. In the case of no more limitation, the element defined by the sentence “includes a . . . ” does not exclude the existence of another identical element in the process, the method, or the device including the element.

It is to be noted that the embodiments disclosed herein are described in an inter-related manner with the description of each embodiment focusing on its differences from others, and reference can be made between the embodiments for their identical or similar features. In particular, since the apparatus, electronic device and computer-readable storage medium embodiments are substantially similar to the method embodiments, they are described relatively briefly, and reference can be made to the method embodiments for details of them.

The description presented above is merely that of a few preferred embodiments of the present invention and is not intended to limit the scope thereof in any sense. Any and all changes, equivalent substitutions, modifications and the like made within the spirit and concept of the present invention are intended to fall within the scope within the scope thereof.

1. A modeling method for an optical proximity correction (OPC) model, the modeling method comprising:
configuring N sets of OPC test patterns with different pattern densities, where N is greater than or equal to 2; and
creating the OPC model by utilizing the OPC test patterns, the OPC model comprising variation of a critical dimension (CD) of a test pattern with pattern density.

2. The modeling method of claim 1, wherein each of the sets of OPC test patterns with different pattern densities at least comprises a primary pattern Pᵢ and at least one auxiliary pattern Aᵢ each provided around the primary pattern Pᵢ at a distinct designed distance from the primary pattern Pᵢ.

3. The modeling method of claim 2, wherein creating the OPC model by utilizing the OPC test patterns comprises:
collecting wafer data for each of the sets of OPC test patterns with different pattern densities, wherein the wafer data comprises an actual on-wafer CD of the primary pattern Pᵢ, and based on the wafer data, establishing a mapping relationship reflecting variation of the actual on-wafer CD of the primary pattern Pᵢ with pattern density of OPC test patterns, as the OPC model.

4. The modeling method of claim 3, wherein the pattern density comprises local pattern density or global pattern density.

5. The modeling method of claim 4, wherein the local pattern density is a percentage of an aggregate area of a plurality of auxiliary patterns Aᵢ within a predetermined region in an area of the predetermined region.

6. The modeling method of claim 5, wherein the predetermined region has a size of X*Y, where X ranges from 30 nm to 1000 nm, and Y ranges from 30 nm to 1000 nm.

7. The modeling method of claim 3, wherein the mapping relationship reflecting variation of the actual on-wafer CD of the primary pattern Pᵢ with pattern density of OPC test patterns comprises:
a function describing variation of the actual on-wafer CD of the primary pattern Pᵢ with a designed area of an auxiliary pattern Aᵢ and a designed distance between the primary pattern Pᵢ and the auxiliary pattern Aᵢ; and/or
a function describing variation of the actual on-wafer CD of the primary pattern Pᵢ with a ratio of a designed area of an auxiliary pattern Aᵢ within a predetermined region to an area of the predetermined region.

8. The modeling method of claim 7, wherein the square root of the designed area of the auxiliary pattern Aᵢ is greater than 10 times the CD of the primary pattern Pᵢ.

9. The modeling method of claim 7, wherein the distance between the primary pattern Pᵢ and the auxiliary pattern Aᵢ is not greater than 100 times the CD of the primary pattern Pᵢ.

10. A modeling system for an optical proximity correction (OPC) model, which is used to implement the modeling method of claim 1, the modeling system comprising:
an OPC test pattern configuration module for configuring N sets of OPC test patterns with different pattern densities, where N is greater than or equal to 2, each of the sets of OPC test patterns with different pattern densities at least comprising a primary pattern Pᵢ and at least one auxiliary pattern Aᵢ each provided around the primary pattern Pᵢ at a distinct designed distance from the primary pattern Pᵢ; and
a model creation module for collecting wafer data for each of the sets of OPC test patterns with different pattern densities, which comprises an actual on-wafer critical dimension (CD) of the primary pattern Pᵢ, and based on the wafer data, establishing a mapping relationship reflecting variation of the actual on-wafer CD of the primary pattern Pᵢ with pattern density of OPC test patterns, as the OPC model.

11. An optical proximity correction (OPC) method, comprising:
creating an OPC model using a modeling method of claim 1, which adds a mapping relationship between a critical dimension (CD) of a pattern and pattern density-related variables;
determining a test layout corresponding to a prefabricated layout, which has at least one pattern to be corrected, and determining pattern density of the pattern to be corrected in the test layout using a predefined pattern detection strategy; and
based on the determined pattern density and the mapping relationship in the OPC model, determining a CD correction amount for the pattern to be corrected for the current OPC run and performing an OPC operation on the pattern to be corrected according to the CD correction amount.

12. The OPC method of claim 11, wherein the mapping relationship that adds the mapping relationship between the CD of the pattern and the pattern density-related variables comprises:
a function describing variation of an actual on-wafer CD of a primary pattern Pᵢ with a designed area of an auxiliary pattern Aᵢ and a designed distance between the primary pattern Pᵢ and the auxiliary pattern Aᵢ; and/or
a function describing variation of an actual on-wafer CD of a primary pattern Pᵢ with a ratio of a designed area of an auxiliary pattern Aᵢ within a predetermined region to an area of a predetermined region.

13. The OPC method of claim 12, wherein determining the pattern density of the pattern to be corrected in the test layout using the predefined pattern detection strategy comprises:
detecting an area of a surrounding pattern of the pattern to be corrected, and determining an area value of the surrounding pattern whose area is greater than a predetermined threshold and a distance between the surrounding pattern and the pattern to be corrected.

14. The OPC method of claim 13, wherein determining the CD correction amount for the pattern to be corrected for the current OPC run based on the determined pattern density and the mapping relationship in the OPC mode comprises:
inputting the area value and the distance to the function in the OPC model that describes variation of the actual on-wafer CD of the primary pattern Pᵢ with the designed area of the auxiliary pattern Aᵢ and the designed distance between the primary pattern Pᵢ and the auxiliary pattern Aᵢ and taking a difference between an output of the function and a designed CD for the pattern to be corrected as the CD correction amount for the pattern to be corrected for the current OPC run.

15. The OPC method of claim 14, wherein determining the pattern density of the pattern to be corrected in the test layout using the predefined pattern detection strategy comprises:
setting a predetermined region around the pattern to be corrected, the predetermined region encompassing the pattern to be corrected and a plurality of surrounding patterns each spaced from the pattern to be corrected at a certain distance; and
determining an area of the predetermined region and an aggregate area of all the surrounding patterns except for the pattern to be corrected contained in the predetermined region.

16. The OPC method of claim 15, wherein determining the CD correction amount for the pattern to be corrected for the current OPC run based on the determined pattern density and the mapping relationship in the OPC mode comprises:
inputting the area of the predetermined region and the aggregate area of all the surrounding patterns except for the pattern to be corrected contained in the predetermined region to the function in the OPC model that describes variation of the actual on-wafer CD of the primary pattern Pᵢ with the ratio of the designed area of the auxiliary pattern Aᵢ within the predetermined region to the area of the predetermined region and taking a difference between an output of the function and the designed CD for the pattern to be corrected as the CD correction amount for the pattern to be corrected for the current OPC run.

17. The OPC method of claim 16, wherein determining the CD correction amount for the pattern to be corrected for the current OPC run based on the determined pattern density and the mapping relationship in the OPC mode comprises:
inputting the area value, the distance, the area of the predetermined region and the aggregate area of all the surrounding patterns except for the pattern to be corrected contained in the predetermined region into the OPC model and taking a difference between an output of the OPC model and the designed CD for the pattern to be corrected as the CD correction amount for the pattern to be corrected for the current OPC run.

18. The OPC method of claim 17, wherein the square root of the area of the surrounding pattern of the pattern to be corrected is greater than 10 times the CD of the pattern to be corrected.

19. The OPC method of claim 17, wherein the distance between the surrounding pattern and the pattern to be corrected is not greater than 100 times the CD of the pattern to be corrected.

20. An optical proximity correction (OPC) method, comprising:
creating an OPC model using a modeling method of claim 1, which adds a mapping relationship between a critical dimension (CD) of a pattern and pattern density-related variables;
determining a test layout corresponding to a prefabricated layout, which has at least one pattern to be corrected, and determining pattern density of the pattern to be corrected in the test layout using a predefined pattern detection strategy; and
based on the determined pattern density and the mapping relationship in the OPC model, determining a CD correction amount for the pattern to be corrected for the current OPC run and performing an OPC operation on the pattern to be corrected according to the CD correction amount, wherein the OPC method is implemented by an OPC system, the OPC) system comprising:
a modeling module for creating an OPC model using the modeling method, which adds a mapping relationship between a critical dimension (CD) of a pattern and pattern density-related variables;
a pattern density determination module for determining a test layout corresponding to a prefabricated layout, which has at least one pattern to be corrected, and determining pattern density of the pattern to be corrected in the test layout using a predefined pattern detection strategy; and
a correction module for determining, based on the determined pattern density and the mapping relationship in the OPC model, a CD correction amount for the pattern to be corrected for the current OPC run and performing an OPC operation on the pattern to be corrected according to the CD correction amount.
